(19) United States
(12) Patent Application Publication
(10) Pub. No.: US 2022/0084953 A1
(43) Pub. Date: Mar. 17, 2022

(54) SEMICONDUCTOR DEVICE AND METHOD FOR MANUFACTURING THE SAME

(71) Applicant: Kioxia Corporation, Tokyo (JP)

(72) Inventors: Masaki NOGUCHI, Yokkaichi Mie (JP); Tatsunori ISOGAI, Yokkaichi Mie (JP)

(21) Appl. No.: 17/190,259

(22) Filed: Mar. 2, 2021

(30) Foreign Application Priority Data
Sep. 17, 2020 (JP) 2020-156637

(51) Int. Cl. H01L 23/532; H01L 27/1157; H01L 27/11582; H01L 23/528; H01L 21/768

(52) U.S. Cl. CPC H01L 23/53295; H01L 27/1157; H01L 21/76826; H01L 23/53266; H01L 23/5283; H01L 27/11582

(57) ABSTRACT

A semiconductor device includes a stacked film including a plurality of electrode layers and a plurality of insulating layers that are alternatively positioned. Furthermore, the device includes a first insulating film, a charge storage layer, a second insulating film, a semiconductor layer in successive positioning, and a third insulating film. The third insulating film is provided between the electrode layers and the insulating layers and between the electrode layers and the first insulating film, and contains an aluminum element and an oxygen element. A minimum thickness of the third insulating film between the electrode layers and the first insulating film is larger than a minimum thickness of the third insulating film between the electrode layers and the insulating layers.

### CROSS-REFERENCE TO RELATED APPLICATION(S)

This application is based upon and claims the benefit of priority from Japanese Patent Application No. 2020-156637, filed Sep. 17, 2020, the entire contents of which are incorporated herein by reference.

### FIELD

Embodiments described herein relate generally to a semiconductor device and a method for manufacturing the same.

### BACKGROUND

When in a process of replacing a three-dimensional memory, an electrode layer is formed through a block insulating film between insulating layers of a stacked film, a decrease in performance of the electrode layer, such as an increase in resistance of the electrode layer, due to the block insulating film may occur.

### DESCRIPTION OF THE DRAWINGS

FIG. 1 is a perspective view illustrating a structure of a semiconductor device of a first embodiment.

FIG. 2 is a cross-sectional view illustrating the structure of the semiconductor device of the first embodiment.

FIG. 3 is an enlarged cross-sectional view illustrating the structure of the semiconductor device of the first embodiment.

FIG. 4A and FIG. 4B are cross-sectional views (1/4) illustrating a method for manufacturing the semiconductor device of the first embodiment.

FIG. 5A and FIG. 5B are cross-sectional views (2/4) illustrating the method for manufacturing the semiconductor device of the first embodiment.

FIG. 6A and FIG. 6B are cross-sectional views (3/4) illustrating the method for manufacturing the semiconductor device of the first embodiment.

FIG. 7A and FIG. 7B are cross-sectional views (4/4) illustrating the method for manufacturing the semiconductor device of the first embodiment.

FIG. 8 is a cross-sectional view illustrating a structure of a semiconductor device of a second embodiment.

FIG. 9A and FIG. 9B are cross-sectional views illustrating a method for manufacturing the semiconductor device of the second embodiment.

### DETAILED DESCRIPTION

Embodiments provide a semiconductor device capable of preventing a decrease in performance of an electrode layer and a method for manufacturing the same.

In general, according to one embodiment, a semiconductor device includes a stacked film including a plurality of electrode layers and a plurality of insulating layers that are alternated. Furthermore, the device includes a first insulating film, a charge storage layer, a second insulating film, and a semiconductor layer that are successively provided in the stacked film. In addition, the device includes a third insulating film. The third insulating film is provided between the electrode layers and the insulating layers and between the electrode layers and the first insulating film, and contains an aluminum element and an oxygen element. The minimum value of film thickness of the third insulating film provided between the electrode layers and the first insulating film is larger than the minimum value of film thickness of the third insulating film provided between the electrode layers and the insulating layers.

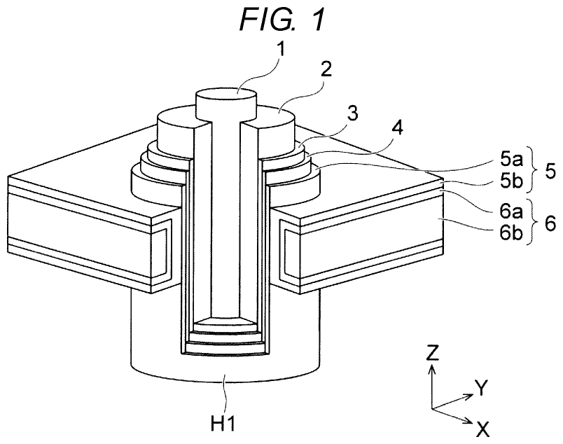

Hereinafter, embodiments will be described with reference to the drawings. In FIG. 1 to FIG. 9B, the same elements are denoted with the same numbers and characters, and duplicated description is omitted.

### First Embodiment

FIG. 1 is a perspective view illustrating a structure of a semiconductor device of a first embodiment. For example, the semiconductor device of FIG. 1 is a three-dimensional NAND memory.

The semiconductor device of FIG. 1 includes a core insulating film 1, a channel semiconductor layer 2, a tunnel insulating film 3, a charge storage layer 4, a block insulating film 5, and an electrode layer 6. The block insulating film 5 includes a block insulating film 5a provided on a side of the charge storage layer 4 and a block insulating film 5b provided on a side of the electrode layer 6. The electrode layer 6 includes a barrier metal layer 6a and an electrode material layer 6b. The block insulating film 5a is an example of a first insulating film, the tunnel insulating film 3 is an example of a second insulating film, and the block insulating film 5b is an example of a third insulating film.

In FIG. 1, a plurality of electrode layers and a plurality of insulating layers are alternately stacked on a substrate, and a memory hole H1 is provided in the electrode layers and the insulating layers. In FIG. 1, the electrode layer 6 is shown as one of these electrode layers. For example, the electrode layers function as a word line of a NAND memory. In FIG. 1, an X direction and a Y direction that are parallel to a surface of the substrate and are perpendicular to each other, and a Z direction that is perpendicular to the surface of the substrate are shown. In this specification, a +Z direction is used as an upward direction, and a −Z direction is used as a downward direction. The −Z direction may or may not be accord with a direction of gravity.

The core insulating film 1, the channel semiconductor layer 2, the tunnel insulating film 3, the charge storage layer 4, and the block insulating film 5a are formed in the memory hole H1, to constitute a memory cell of the NAND memory. The block insulating film 5a is formed on surfaces of the electrode layers and the insulating layers in the memory hole H1. The charge storage layer 4 is formed on a surface of the block insulating film 5a. In the charge storage layer 4, a charge can be stored between an outer surface and an inner side. The tunnel insulating film 3 is formed on a surface of the charge storage layer 4. The channel semiconductor layer 2 is formed on a surface of the tunnel insulating film 3. The channel semiconductor layer 2 functions as a channel of the memory cell. The core insulating film 1 is formed in the channel semiconductor layer 2.

For example, the core insulating film 1 is a silicon oxide film (SiO₂ film). For example, the channel semiconductor layer 2 is a polysilicon layer. For example, the tunnel insulating film 3 is a SiO₂ film or a stacked film including a SiO₂ film and a silicon oxynitride film (SiON film). For example, the charge storage layer 4 is a silicon nitride film (SiN film). For example, the block insulating film 5a is a SiO₂ film.

The block insulating film 5b, the barrier metal layer 6a, and the electrode material layer 6b are formed between the insulating layers that are adjacent to each other. A lower surface of the upper insulating layer, an upper surface of the lower insulating layer, and a side surface of the block insulating film 5a are successively formed. For example, the block insulating film 5b is an insulating film containing an aluminum element and an oxygen element, and in particular, an aluminum oxide film (Al₂O₃ film). For example, the barrier metal layer 6a is a titanium nitride film (TiN film). For example, the electrode material layer 6b is a tungsten (W) layer or a molybdenum (Mo) layer. When the electrode material layer 6b is a Mo layer, each of the electrode layers 6 may not include the barrier metal layer 6a.

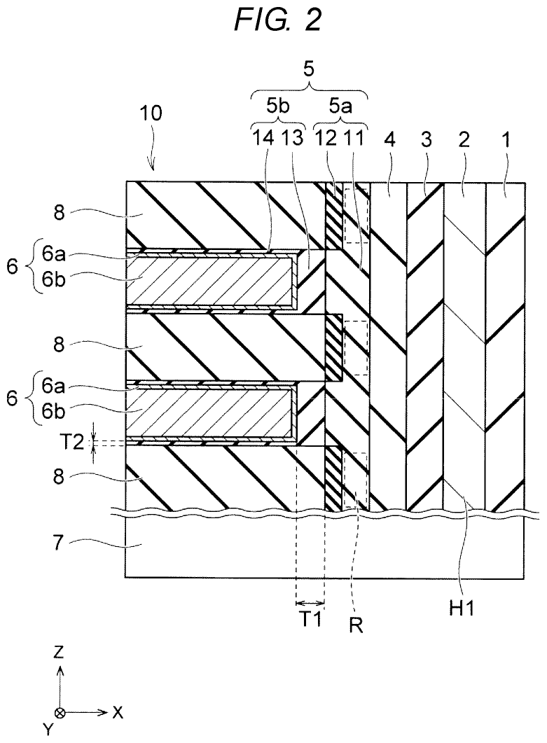

FIG. 2 is a cross-sectional view illustrating the structure of the semiconductor device of the first embodiment.

As illustrated in FIG. 2, the semiconductor device of the embodiment includes a substrate 7 and a stacked film 10 including a plurality of the electrode layers 6 and a plurality of insulating layers 8 that are alternately stacked above the substrate 7. For example, the substrate 7 is a semiconductor substrate such as a silicon substrate. For example, each of the electrode layers 6 contains the barrier metal layer 6a such as a TiN film and the electrode material layer 6b such as a W film, as described above. For example, each of the insulating layers 8 is a SiO₂ film. The aforementioned memory hole H1 is provided in the stacked film 10, as illustrated in FIG. 2.

As illustrated in FIG. 2, the semiconductor device of the embodiment further includes the block insulating film 5a, the charge storage layer 4, the tunnel insulating film 3, the channel semiconductor layer 2, and the core insulating film 1 that are successively formed in the memory hole H1 of the stacked film 10. The block insulating film 5a includes an insulating film 11 provided on a side of the charge storage layer 4 and a plurality of insulating films 12 provided on a side of the stacked film 10. For example, the insulating film 11 and the insulating films 12 are a SiO₂ film. Each of the insulating films 12 of the embodiment is formed on a side surface of each of the insulating layers 8.

The insulating film 11 of the embodiment is formed by changing a part of the charge storage layer 4 (SiN film) into the insulating film 11 (SiO₂ film) under oxidation, as described below. At that time, the SiN film may remain as it is at a plurality of regions R illustrated in FIG. 2. In this case, the regions R are a part of the charge storage layer 4, but not a part of the insulating film 11. The regions R are positioned near to side surfaces of the insulating films 12, and are protruded in a direction toward the insulating films 12 and the insulating layers 8 from the charge storage layer 4 in the insulating film 11.

Each of the electrode layers 6 is formed between the insulating layers 8 that are adjacent to each other through the block insulating film 5b. Each of the block insulating films 5b is formed on a lower surface of an upper insulating layer 8, an upper surface of a lower insulating layer 8, and the side surface of the block insulating film 5a. As a result, the block insulating films 5b each includes a portion 13 provided between the electrode layers 6 and the block insulating film 5a and a portion 14 provided between the electrode layers 6 and the insulating layers 8. The portion 13 is formed on the side surface of the block insulating film 5a. The portion 14 is formed on the lower surface of the upper insulating layer 8 and the upper surface of the lower insulating layer 8.

In this embodiment, a film thickness T1 of the portion 13 of each of the block insulating films 5b is set to be larger than a film thickness T2 of the portion 14 of each of the block insulating films 5b. For example, the film thickness T1 is set to be two or more times the film thickness T2 of the portion 14 of each of the block insulating films 5b. When the film thickness T1 of the portion 13 is small, a blocking action of the block insulating films 5b may be insufficient. When the film thickness T2 of the portion 14 is large, the volume of each of the electrode layers 6 is small. Therefore, the resistance of the electrode layers 6 may be increased. According to the embodiment, the film thickness T1 of the portion 13 is set to be larger than the film thickness T2 of the portion 14. This makes it possible to improve the blocking action of the block insulating films 5b or to decrease the resistance of the electrode layers 6.

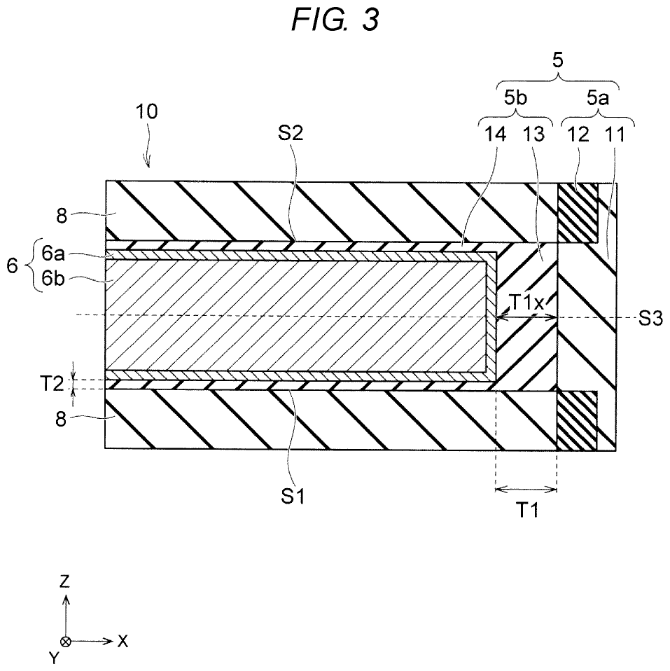

When the degree of integration of the NAND memory is increased, the distance between the adjacent insulating layers 8 may be decreased. In this case, a problem in which the resistance of the electrode layers 6 is increased may be more severe. According to the embodiment, the film thickness T1 of the portion 13 is set to be larger than the film thickness T2 of the portion 14. This makes it possible to effectively solve this problem. The details of the film thicknesses T1 and T2 will be described below with reference to FIG. 3.

FIG. 3 is an enlarged cross-sectional view illustrating the structure of the semiconductor device of the first embodiment.

FIG. 3 illustrates the insulating layers 8 that are adjacent to each other, and the corresponding block insulating film 5b and the corresponding electrode layer 6 that are provided between these insulating layers 8. Furthermore, FIG. 3 illustrates an upper surface S1 of the lower insulating layer 8, a lower surface S2 of the upper insulating layer 8, and a cross-sectional surface (XY plane) S3 positioned between the upper surface S1 and the lower surface S2. In FIG. 3, the film thickness T1 of the portion 13 of the block insulating film 5b at the height of the cross-sectional surface S3 is represented by a reference symbol T1x.

The portion 13 of the block insulating film 5b of the embodiment is formed by layering two Al₂O₃ films, as described below. Therefore, the film thickness T1 of the portion 13 may be ununiform. Furthermore, when the distance between the adjacent insulating layers 8 is decreased, the film thickness T1 of the portion 13 maybe ununiform. Accordingly, a relationship between the film thicknesses T1 and T2 is desirably defined in consideration of possibility in which the film thickness T1 of the portion 13 is ununiform.

Herein, the reference symbol T1x in FIG. 3 represents the minimum value of the film thickness T1 of the portion 13 of the block insulating film 5b. In this embodiment, the minimum value T1x of the film thickness T1 of the portion 13 is set to be larger than the film thickness T2 of the portion 14 (Tx1>T2). For example, the minimum value T1x is set to be two or more times the film thickness T2 of the portion 14 (Tx1≥2×T2). Therefore, even when the film thickness T1 of the portion 13 is ununiform, the blocking action of the block insulating film 5b can be improved, or the resistance of the electrode layer 6 can be decreased.

The cross-sectional surface S3 when the film thickness T1 of the portion is the minimum value T1x may be at any position between the upper surface S1 and the lower surface S2. In FIG. 3, the cross-sectional surface S3 is at a middle height between the height of the upper surface S1 and the height of the lower surface S2.

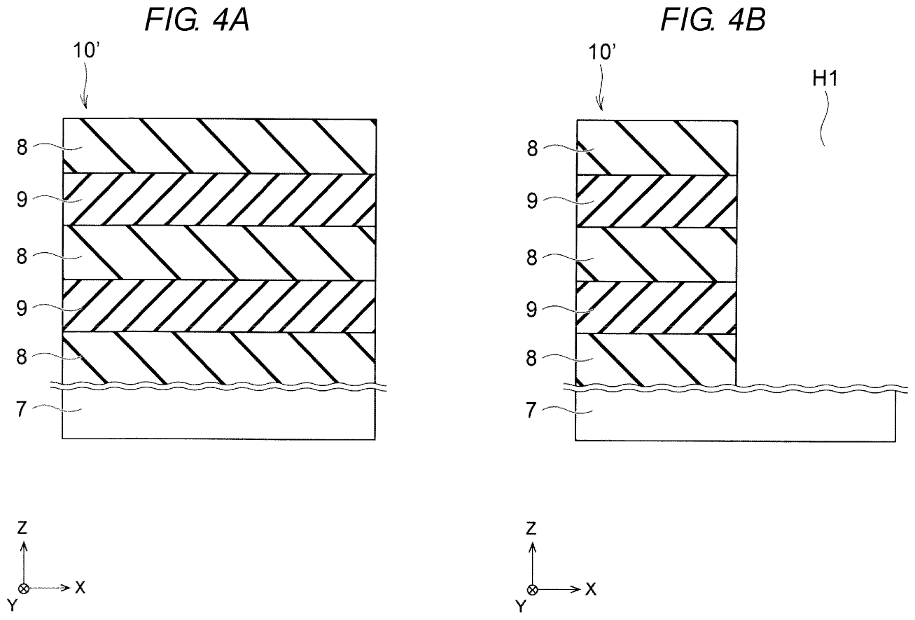

FIG. 4A to FIG. 7B are cross-sectional views illustrating a method for manufacturing the semiconductor device of the first embodiment.

Above the substrate 7, a stacked film 10′ including a plurality of sacrificial layers 9 and a plurality of the insulating layers 8 that are alternated is formed (FIG. 4A). For example, the sacrificial layers 9 are a SiN film. The sacrificial layers 9 are an example of a first layer.

Subsequently, the memory hole H1 is formed in the stacked film 10′ by lithography and reactive ion etching (RIE) (FIG. 4B). The memory hole H1 penetrates the stacked film 10′.

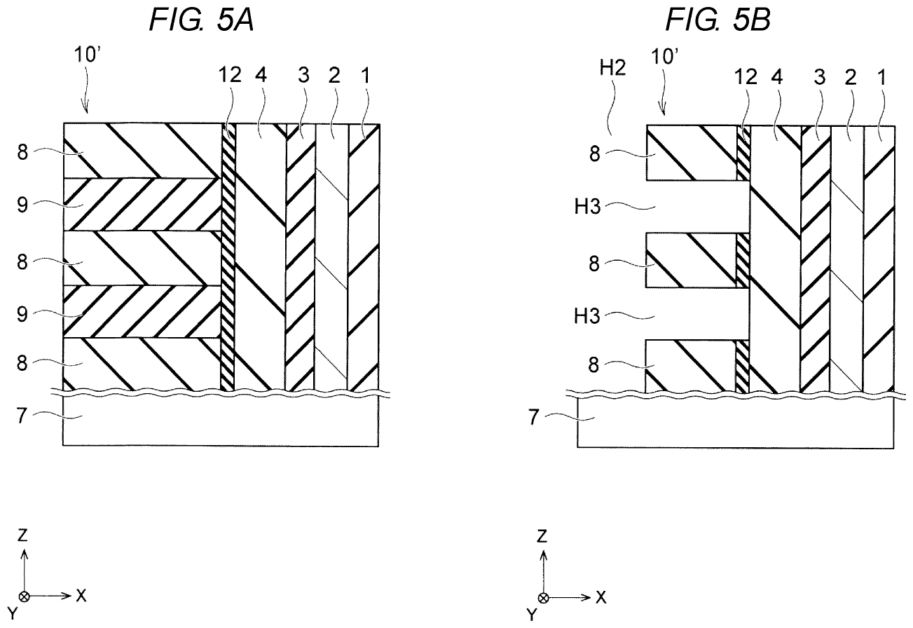

Next, the insulating film 12, the charge storage layer 4, the tunnel insulating film 3, the channel semiconductor layer 2, and the core insulating film 1 are successively formed in the memory hole H1 (FIG. 5A). As described above, for example, the insulating film 12 is a SiO₂ film, and the charge storage layer 4 is a SiN film. In a step of FIG. 5A, the film thickness of the charge storage layer 4 is set to be larger than the film thickness of the charge storage layer 4 of a manufactured semiconductor device (see FIG. 1 to FIG. 3). The insulating film 12 is an example of a first portion.

Subsequently, a slit H2 is formed in the stacked film 10′ by chemical dry etching (CDE) (FIG. 5B). The slit H2 has an extending shape in the Y and Z directions. The slit H2 penetrates the stacked film 10′. Next, the sacrificial layers 9 are removed by CDE from the slit H2 (FIG. 5B). As a result, a plurality of recess portions H3 are formed between the insulating layers 8. Subsequently, a part of the insulating film 12 is removed by CDE from the recess portions H3 (FIG. 5B). Specifically, a portion of the insulating film 12 that is exposed to the recess portions H3 is removed. As a result, the insulating layer 12 is divided into a plurality of insulating layers 12 that are on the side surfaces of the insulating layers 8. In CDE in a step of FIG. 5B, for example, hydrogen fluoride (HF) and ammonia (NH₃) are used. The insulating films 12 function as an etch stopper during removal of the sacrificial layers 9.

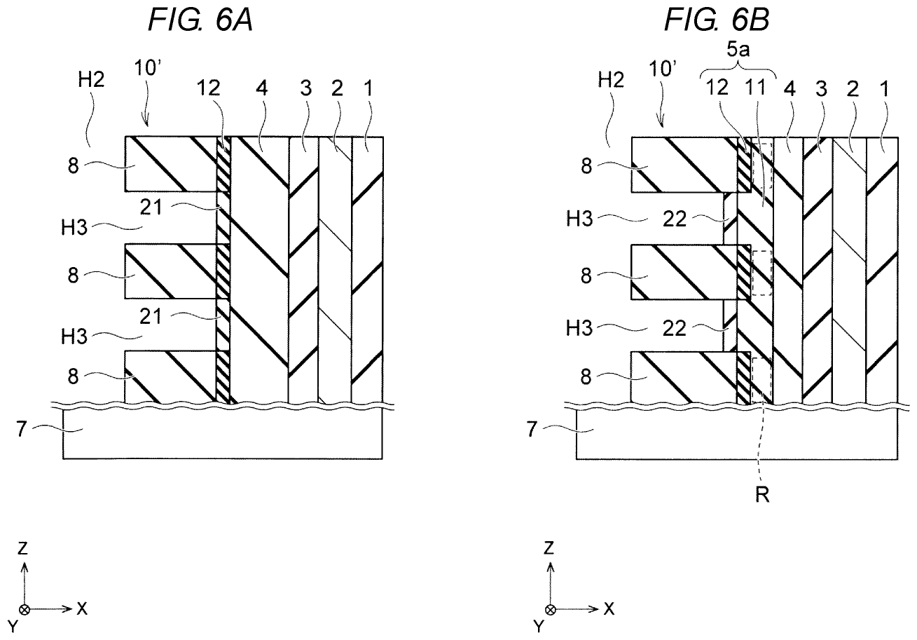

Subsequently, a film 21 is formed on a side surface of the exposed charge storage layer 4 in each of the recess portions H3 by selective growth (FIG. 6A). For example, the films 21 are a film containing an aluminum element and a nitrogen element, and in particular, an aluminum nitride film (AlN film). For example, the selective growth of the films 21 can be achieved by atomic layer deposition (ALD) using trimethylaluminum (TMA, Al(CH₃)₃) and NH₃. In this case, the films 21 can be selectively grown by a difference of incubation time between the SiO₂ film and the SiN film. For example, the formation temperature of the films 21 is 300 to 400° C. In this embodiment, the film thickness of the films 21 is set to be the same as that of the insulating films 12. The films 21 are an example of a first film.

Subsequently, an oxidation process using radicals or plasma is performed (FIG. 6B). As a result, each of the films 21 (AlN film) is oxidized into an insulating film 22 (Al₂O₃ film). The insulating films 22 are an example of a third portion. Furthermore, a part of the charge storage layer 4 (SiN film) is oxidized into the insulating film 11 (SiO₂ film). The insulating film 11 is an example of a second portion. In this embodiment, an oxidation process is performed so that not only the films 21 but also a part of the charge storage layer 4 are oxidized. Thus, portions close to the recess portions H3 in the charge storage layer 4 are oxidized. As a result, the block insulating film 5a including the insulating films 11 and 12 is formed. For example, a nitrogen atom generated by oxidation is emitted in the air as a nitrogen gas (N₂). The block insulating film 5a may be formed so that a boundary surface between the insulating films 11 and 12 can be observed, or may be formed so that the boundary surface between the insulating films 11 and 12 cannot be observed.

In a step of FIG. 6B, when the part of the charge storage layer 4 is changed into the insulating film 11 by oxidation, the volume of the insulating film 11 is increased. Therefore, the positions of the insulating films 22 in FIG. 6B are shifted toward a side of the recess portions H3 as compared with the positions of the films 21 in FIG. 6A. Similarly, when the films 21 are changed into the insulating films 22 by oxidation, the volume of the insulating films 22 is increased. In addition, the volume of the insulating layers 8 is increased in the step of FIG. 6B.

A mechanism of increasing the volumes of the insulating film 11 and the like is as follows. By oxidation of the insulating film 11 and the like, a bond between a Si atom (or an Al atom) and a N atom is broken, and the SI atom (or the Al atom) and an O atom are bonded. The film density (g/cm³) of a Si—O bond (or Al—O bond) is smaller than that of a Si—N bond (or an Al—N bond). Therefore, the volume after oxidation is larger than the volume before oxidation as long as the number of Si atoms (or Al atoms) is not changed. As a result, the volume of the insulating film 11 and the like is increased. For example, when the SiN film is changed into the SiO₂ film, the film thickness is increased about 1.8 times due to volumetric expansion. When the AlN film is changed into the Al₂O₃ film, the film thickness is increased about 1.5 times due to volumetric expansion.

In the step of FIG. 6B, the SiN film at the regions R illustrated in FIG. 6B may not be changed into the SiO₂ film by oxidation and may remain as it is. In this case, the regions R are a part of the charge storage layer 4, but not a part of the insulating film 11. The regions R are positioned near to the side surfaces of the insulating films 12, and are protruded in a direction toward the insulating films 12 and the insulating layers 8 from the charge storage layer 4 in the insulating film 11.

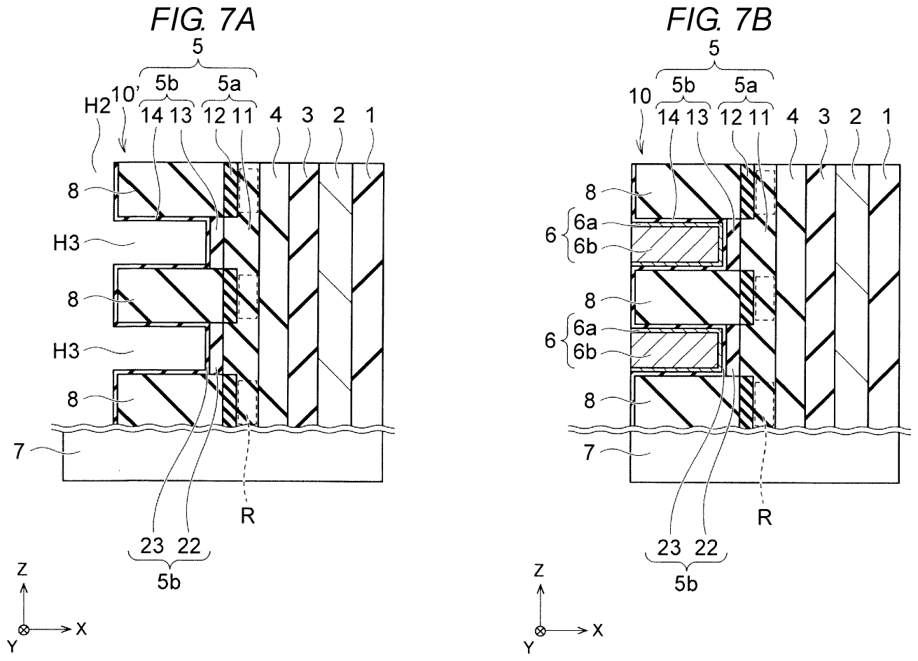

Subsequently, an insulating film 23 is formed on an upper surface, a lower surface, and a side surface of each of the recess portions H3 and the like by ALD (FIG. 7A). As a result, the insulating film 23 is formed on the lower surface of the upper insulating layer 8, the upper surface of the lower insulating layer 8, and the side surface of the insulating film in each of the recess portions H3. For example, the insulating film 23 is an Al₂O₃ film. The insulating film 23 is an example of a fourth portion. Thus, each of the block insulating films 5b including the insulating films 22 and 23 is formed. Each of the block insulating films 5b includes the portion 13 formed on the side surface of the block insulating film 5a and the portion 14 formed on the lower surface of the upper insulating layer 8 and the upper surface of the lower insulating layer 8.

In consideration of film thickness of the insulating films 22, the film thickness of the insulating film 23 is set in the step of FIG. 7A so that the film thickness T1 (FIG. 2) of the portion 13 is a desired thickness. This makes it possible to form the block insulating films 5b having a sufficient blocking action. In this embodiment, the film thickness T1 of the portion 13 is the total film thickness of the insulating films 22 and 23, and the film thickness T2 (FIG. 2) of the portion 14 is the film thickness of the insulating film 23. Therefore, the film thickness T1 is larger than the film thickness T2. In this embodiment, the film thickness of each of the insulating films 22 is set to be equal to or more than the film thickness of the insulating film 23. Therefore, the film thickness T1 is two or more times the film thickness T2.

In the step of FIG. 7A, the minimum value T1x (FIG. 3) of the film thickness T1 of the portion 13 is desirably set to be larger than the film thickness T2 of the portion 14 (Tx1>T2). For example, the minimum value T1x is desirably set to be two or more times the film thickness T2 of the portion 14 (Tx1≥2×T2). Therefore, even when the film thickness T1 of the portion 13 is ununiform, the blocking action of the block insulating films 5b can be improved, or the resistance of the electrode layers 6 can be decreased. In the embodiment, the film thickness of each of the insulating films 22 is desirably set to be sufficiently larger than the film thickness of the insulating film 23 so as to satisfy these relationships.

Next, the barrier metal layer 6a and the electrode material layer 6b are successively formed in each of the recess portions H3 through each of the block insulating films 5b (FIG. 7B). As a result, the electrode layers 6 each including the barrier metal layer 6a and the electrode material layer 6b are formed in the recess portions H3. Thus, the stacked film 10 including the electrode layers 6 and the insulating layers 8 that are alternated is formed above the substrate 7. A treatment in which the sacrificial layers 9 are removed to form the electrode layers 6 is called replace treatment. The barrier metal layer 6a and the electrode material layer 6b that are excess in the slit H2 are removed, and the slit H2 is then filled with the insulating film. At that time, the insulating film 23 that is excess in the slit H2 may also be removed.

For example, the electrode material layer 6b is a W layer, as described above. In this case, the electrode material layer 6b is formed, for example, by using WF₆ gas. A fluorine (F) atom in the WF₆ gas may be reacted with the Al₂O₃ film. Therefore, a Mo layer may be used for the electrode material layer 6b instead of the W layer. Thus, the electrode material layer 6b can be formed by using a source gas containing no F atom. When the electrode material layer 6b is a Mo layer, each of the electrode layers 6 may not include the barrier metal layer 6a.

Subsequently, various interlayer insulating films, a plug layer, a wiring layer, and the like are formed above the substrate 7. Thus, the semiconductor device of the embodiment is produced (FIG. 1 to FIG. 3).

As described above, the block insulating films 5b of the embodiment are formed so that the minimum value T1x of the film thickness T1 of the portion 13 of each of the block insulating films 5b is larger than the film thickness T2 of the portion 14 of each of the block insulating films 5b (Tx1>T2). Therefore, according to the embodiment, a decrease in performance of the electrode layers 6 such as an increase in resistance of the electrode layers 6 can be prevented.

### Second Embodiment

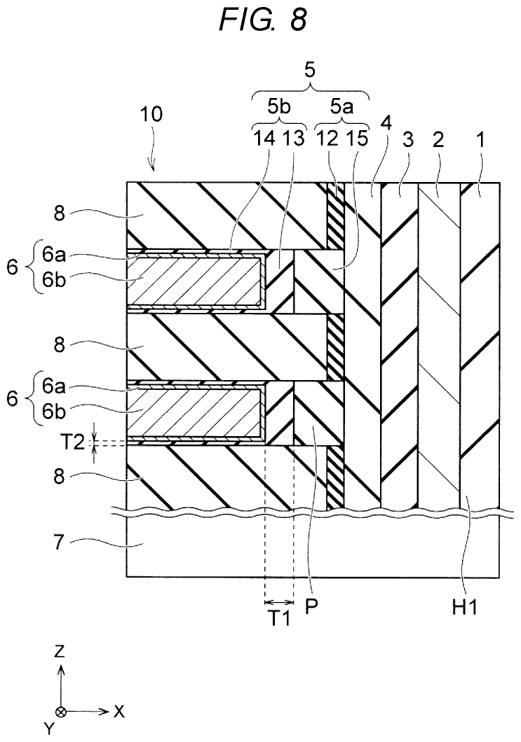

FIG. 8 is a cross-sectional view illustrating a structure of a semiconductor device of a second embodiment.

As illustrated in FIG. 8, the semiconductor device of the embodiment includes the same components as those of the semiconductor device of the first embodiment. The block insulating film 5a of the embodiment includes a plurality of insulating layers 12 positioned near to the side surfaces of the insulating layers 6 and a plurality of insulating layers 15 positioned near to the side surface of the block insulating films 5b. For example, the insulating films 12 and the insulating films 15 are a SiO₂ film. Furthermore, the block insulating film 5a of the embodiment includes a plurality of portions P that are protruded toward the electrode layers 6 between the insulating layers 8 in the insulating films 15. This can eliminate the need for tuning during formation of the channel semiconductor layer 2 and the core insulating film 1. A method for forming the portions P will be described below.

The film thicknesses T1 and T2 of the embodiment are the same as those of the first embodiment. In the embodiment, the film thickness T1 of the portion 13 of each of the block insulating films 5b is set to be larger than the film thickness T2 of the portion 14 of each of the block insulating films 5b. For example, the film thickness T1 is set to be two or more times the film thickness T2 of the portion 14 of each of the block insulating films 5b. In the embodiment, the minimum value T1x (see FIG. 3) of the film thickness T1 of the portion 13 is desirably set to be larger than the film thickness T2 of the portion 14 (Tx1>T2). For example, the minimum value T1x is desirably set to be two or more times the film thickness T2 of the portion 14 (Tx1≥2×T2).

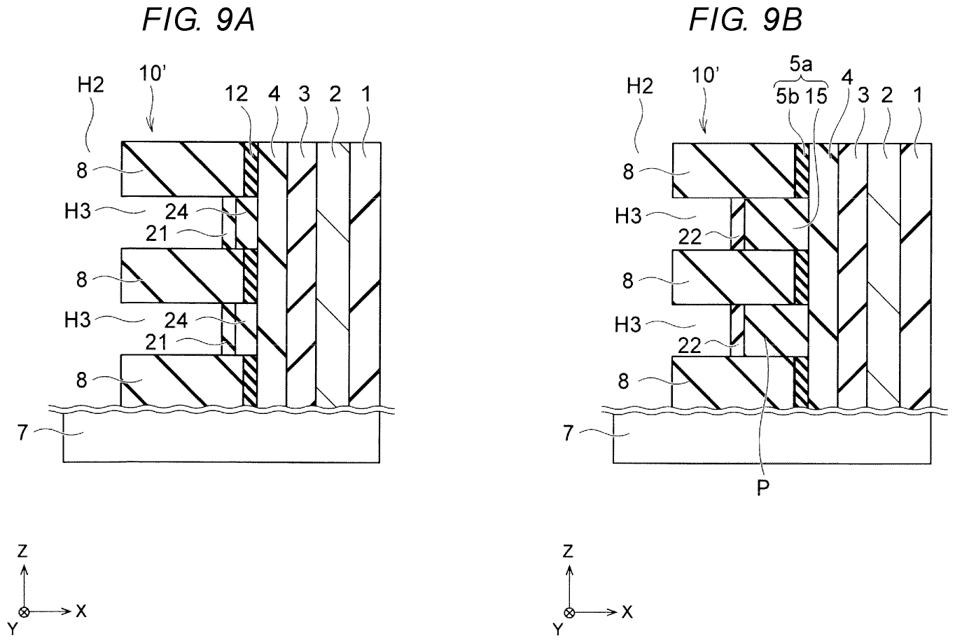

FIG. 9A and FIG. 9B are cross-sectional views illustrating a method for manufacturing the semiconductor device of the second embodiment.

After the steps of FIG. 4A to FIG. 5B, a film 24 is formed on the side surface of the exposed charge storage layer 4 in each of the recess portions H3 by selective growth (FIG. 9A). For example, the films 24 are a film containing a silicon element and a nitrogen element, and in particular, a SiN film. In this embodiment, the film thickness of the films 24 is set to be larger than the film thickness of the insulating films 12. The films 24 are an example of a second film. In the step of FIG. 5A of the embodiment, the film thickness of the charge storage layer 4 is set to be the same as the film thickness of the charge storage layer 4 of a manufactured semiconductor device (see FIG. 8).

Subsequently, the film 21 is formed on a side surface of the film 24 in each of the recess portions H3 by selective growth (FIG. 9A). For example, the films 21 are a film containing an aluminum element and a nitrogen element, and in particular, an AlN film. In this embodiment, the film thickness of the films 21 is set to be the same as that of the insulating films 12. The films 21 are an example of the first film.

Subsequently, an oxidation process using radicals or plasma is performed (FIG. 9B). As a result, each of the films 21 (AlN film) is oxidized and changed into an insulating film 22 (Al₂O₃ film). The insulating films 22 are an example of the third portion. Furthermore, the films 24 (SiN film) are oxidized into the insulating films 15 (SiO₂ film). The insulating films 15 are an example of the second portion. In this embodiment, an oxidation process is performed so that not only the films 21 but also the films 24 are oxidized. Thus, the block insulating film 5a including the insulating films 15 and 12 are formed. For example, a nitrogen atom generated by oxidation is emitted in the air as N₂ gas.

In a step of FIG. 9B, when the films 24 are changed into the insulating films 15 by oxidation, the volume of the insulating films 15 is increased. Therefore, the positions of the films 22 in FIG. 9B is shifted toward the side of the recess portions H3 as compared with the positions of the films 21 in FIG. 9A. Similarly, when the films 21 are changed into the insulating films 22 by oxidation, the volume of the insulating films 22 is increased. In addition, the volume of the insulating layers 8 are increased in the step of FIG. 9B.

After the steps of FIG. 7A and FIG. 7B, various interlayer insulating films, a plug layer, a wiring layer, and the like are formed above the substrate 7. Thus, the semiconductor device of the embodiment is produced (FIG. 8).

Like the block insulating films 5b of the first embodiment, the block insulating films 5b of this embodiment are formed so that the minimum value T1x of the film thickness T1 of the portion 13 of each of the block insulating films 5b is larger than the film thickness T2 of the portion 14 of each of the block insulating films 5b (Tx1>T2). Therefore, according to the embodiment, a decrease in performance of the electrode layers 6 such as an increase in resistance of the electrode layers 6 can be prevented.

The block insulating film 5a of the embodiment includes a plurality of portions P that are protruded toward the electrode layers 6 between the insulating layers 8. According to the embodiment, this can eliminate the need for tuning during formation of the channel semiconductor layer 2 and the core insulating film 1.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising
a stacked film including a plurality of electrode layers and a plurality of insulating layers that are alternatively positioned,
a first insulating film, a charge storage layer, a second insulating film, and a semiconductor layer in successive positioning, and
a third insulating film provided between the electrode layers and the insulating layers and between the electrode layers and the first insulating film, the third insulating film containing an aluminum element and an oxygen element,
wherein a minimum thickness of the third insulating film between the electrode layers and the first insulating film is larger than a minimum thickness of the third insulating film between the electrode layers and the insulating layers.

2. The semiconductor device according to claim 1,
wherein the minimum thickness of the third insulating film between the electrode layers and the first insulating film is at least twice as thick as the minimum thickness of the third insulating film between the electrode layers and the insulating layers.

3. The semiconductor device according to claim 1,
wherein the charge storage layer includes a plurality of regions protruded in a direction toward the insulating layers in the first insulating film.

4. The semiconductor device according to claim 1,
wherein the first insulating film includes a plurality of portions protruded in a direction toward the electrode layers between the insulating layers.

5. A method for manufacturing a semiconductor device comprising
forming a stacked film including a plurality of first layers and a plurality of insulating layers that are alternatively positioned,
successively forming a first insulating film, a charge storage layer, a second insulating film, and a semiconductor layer,
removing the first layer,
forming a plurality of electrode layers between the insulating layers through a third insulating film containing an aluminum element and an oxygen element, and
wherein the third insulating film has a minimum a thickness between the electrode layers and the first insulating film is larger than a minimum thickness of the third insulating film provided between the electrode layers and the insulating layers.

6. The method for manufacturing a semiconductor device according to claim 5,
wherein the minimum thickness of the third insulating film between the electrode layers and the first insulating film is at least twice as thick as the minimum thickness of the third insulating film between the electrode layers and the insulating layers.

7. The method for manufacturing a semiconductor device according to claim 5,
wherein forming the first insulating film comprises:
forming a first portion of the first insulating film for the first insulating film during successive formation of the first insulating film, the charge storage layer, the second insulating film, and the semiconductor layer in the stacked film,
removing the first layer,
removing a part of the first portion from a recess portion between the insulating layers, and
changing a part of the charge storage layer into a second portion of the first insulating film.

8. The method for manufacturing a semiconductor device according to claim 7, wherein the changing the part of the charge storage layer includes oxidizing.

9. The method for manufacturing a semiconductor device according to claim 7,
wherein forming the third insulating film comprises:
removing a part of the first portion,
forming a first film on a side surface of the charge storage layer from the recess portion between the insulating layers, the first film containing an aluminum element and a nitrogen element,
changing a part of the charge storage layer into a second portion and changing the first film into a third portion of the third insulating film, and
forming a fourth portion of the third insulating film on an upper surface and a lower surface of the insulating layer, and a side surface of the third portion.

10. The method for manufacturing a semiconductor device according to claim 9, wherein the changing the part of the charge storage layer and changing the first film includes oxidizing.

11. The method for manufacturing a semiconductor device according to claim 5,
wherein forming the first insulating film comprises:
forming a first portion of the first insulating film for the first insulating film during successive formation of the first insulating film, the charge storage layer, the second insulating film, and the semiconductor layer in the stacked film,
removing the first layer,
removing a part of the first portion from a recess portion between the insulating layers,
forming a second film on a side surface of the charge storage layer from the recess portion between the insulating layers, and
changing the second film into a second portion of the first insulating film.

12. The method for manufacturing a semiconductor device according to claim 11, wherein the changing the second film includes oxidizing.

13. The method for manufacturing a semiconductor device according to claim 11,
wherein forming the third insulating film comprises:
removing a part of the first portion,
successively forming the second film and the first film containing an aluminum element and a nitrogen element on a side surface of the charge storage layer from the recess portion between the insulating layers,
changing the second film into the second potion and changing the first film into a third portion of the third insulating film, and
forming a fourth portion of the third insulating film on an upper surface and a lower surface of the insulating layer, and a side surface of the third portion.

14. The method for manufacturing a semiconductor device according to claim 13, wherein the changing the first film includes oxidizing.

15. The method for manufacturing a semiconductor device according to claim 11,
wherein the second film contains a silicon element and a nitrogen element.
